(19) United States
(12) Patent Application Publication
(10) Pub. No.: US 2013/0230948 A1
(43) Pub. Date: Sep. 5, 2013

(54) MULTIPLE STEP IMPLANT PROCESS FOR FORMING SOURCE/DRAIN REGIONS ON SEMICONDUCTOR DEVICES

(71) Applicants: Thilo Scheiper, Dresden (DE); Tom Herrmann, Dresden (DE)

(72) Inventors: Thilo Scheiper, Dresden (DE); Tom Herrmann, Dresden (DE)

(73) Assignee: GLOBALFOUNDRIES INC., Grand Cayman (KY)

(21) Appl. No.: 13/410,793

(22) Filed: Mar. 2, 2012

(51) Int. Cl. H01L 21/336; H01L 21/265

(52) U.S. Cl. 438/151; 438/517; 257/E21.334; 257/E21.409

(57) ABSTRACT

Disclosed herein is a multiple step implantation process to form source/drain regions in semiconductor devices. In one example, the method involves performing an extension implant process to form extension implant regions in a semiconducting substrate comprising a buried insulation layer, forming a patterned mask layer above the substrate and performing at least two source/drain ion implant processes through the patterned mask layer to form doped source/drain implant regions in the substrate, wherein one of the at least two source/drain ion implant processes is performed with a dopant dose that is less than a dopant dose used in another of the at least two source/drain ion implant processes. In further embodiments, one of the at least two source/drain ion implant processes is performed at an implant energy level that is greater than an implant energy level used in another of the at least two source/drain ion implantation processes.

### BACKGROUND OF THE INVENTION

1. Field of the Invention

Generally, the present disclosure relates to the manufacturing of sophisticated semiconductor devices, and, more specifically, to a multiple step implantation process to form source/drain regions in semiconductor devices such as transistors.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Field effect transistors (FETs) represent one important type of circuit element that substantially determines performance of the integrated circuits. Field effect transistors are typically either

NMOS devices or PMOS devices. During the fabrication of complex integrated circuits, millions of transistors, e.g., NMOS transistors and/or PMOS transistors, are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, referred to as a channel region, disposed between the highly doped source/drain regions. The channel length of a MOS transistor is generally considered to be the lateral distance between the source/drain regions.

Ion implantation is a technique that is employed in many technical fields to implant dopant ions into a substrate so as to alter the characteristics of the substrate or of a specified portion thereof. The rapid development of advanced devices in the semiconductor industry is based on, among other things, the ability to generate highly complex dopant profiles within tiny regions of a semiconducting substrate by performing advanced implantation techniques through a masking layer. In the case of an illustrative transistor, ion implantation may be used to form various doped regions, such as halo implant regions, extension implant regions and deep source/drain implant regions, etc.

An illustrative ion implantation sequence for forming source/drain regions for an illustrative prior art transistor 100 will now be discussed with reference to FIGS. 1A-1E. FIG. 1A depicts the transistor 100 at an early stage of fabrication, wherein a gate structure 14 has been formed above a silicon-on-insulator (SOI) substrate 10 that is comprised of a bulk substrate 10A, a buried insulation layer 10B (a so-called BOX layer) and an active layer 10C where semiconductor devices will be formed. An active region 13 is defined in the active layer 10C by a shallow trench isolation structure 11. The gate structure 14 typically includes a gate insulation layer 14A and a conductive gate electrode 14B. The gate structure 14 may be formed by forming layers of material that correspond to the gate insulation layer 14A and the gate electrode 14B and thereafter patterning those layers of material using known etching and photolithography techniques.

The masking layers that would be used during the implantation sequence shown in FIGS. 1A-1E are not depicted in the drawings. As shown in FIG. 1B, an initial ion implantation process 20 is typically performed to form so-called extension implant regions 20A in the substrate 10. Typically, the extension implant regions 20A will be self-aligned with respect to the sidewall of the gate structure 14 (for NMOS devices) or there may be an offset spacer or liner (not shown) formed on the sidewall of the gate structure 14 prior to performing the extension implant process 20 (for a PMOS device). Then, as shown in FIG. 1C, sidewall spacers 16 are formed proximate the gate structure 14. The sidewall spacers 16 are typically formed by conformably depositing a layer of spacer material and thereafter performing an anisotropic etching process. Then, as shown in FIG. 1D, a second ion implantation process 22 is performed on the transistor 100 to form so-called deep source/drain implant regions 22A in the substrate 10. The ion implantation process 22 performed to form the deep source/drain implant regions 22A is typically performed using a higher dopant dose and a higher implant energy than the ion implantation process 20 that is performed to form the extension implant regions 20A. Thereafter, as shown in FIG. 1E, a heating or anneal process is performed to form the final source/drain regions 24 for the transistor 100. This heating process repairs the damage to the lattice structure of the substrate material as a result of the implantation processes and it activates the implanted dopant materials, i.e., the implanted dopant materials are incorporated into the silicon lattice. Of course, the type of dopants implanted, either N-type or P-type dopants, depends upon the type of transistor being made, i.e., an NMOS transistor or a PMOS transistor, respectively. Such implantation processes are performed using well-known ion implantation systems.

In some cases, the aforementioned ion implantation sequence produces final source/drain regions 24 that do not “bottom out” on the upper surface 10S of the buried insulation layer 10B. This situation is depicted in FIG. 1E where the bottom surface 24S of the final source/drain regions 24 is spaced apart from the upper surface 10S of the buried insulation layer 10B. Ideally, all or a substantial portion of the final source/drain regions 24 would contact the upper surface 10S of the buried insulation layer 10B in the region between the sidewall spacer 16 and the isolation structure 11. Bottoming-out of the final source/drain regions 24 is preferred because such a configuration tends to prevent undesirable cross talk between transistors sharing the same active region and such a configuration reduces the geometric ratio of the source/drain regions 24 to the well area, which tends to reduce undesirable leakage currents.

The present disclosure is directed to a multiple step implantation process to form source/drain regions in semiconductor devices, such as transistors, that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a multiple step implantation process to form source/drain regions in semiconductor devices, such as transistors. In one illustrative embodiment, the method involves performing an extension implant process to form extension implant regions in a semiconducting substrate comprising a buried insulation layer, after performing the extension implant process, forming a patterned mask layer above the substrate and performing at least two source/drain ion implant processes through the patterned mask layer to form doped source/drain implant regions in the substrate, wherein one of the at least two source/drain ion implant processes is performed with a dopant dose that is less than a dopant dose used in another of the at least two source/drain ion implant processes. In further, more detailed embodiments, one of the at least two source/drain ion implant processes is performed at an implant energy level that is greater than an implant energy level used in another of the at least two source/drain ion implant processes.

In another illustrative embodiment, the method involves forming a gate structure above an active layer of a semiconducting substrate that comprises a buried insulation layer, performing an extension implant process to form extension implant regions in the active layer and, after performing the extension implant process, forming a sidewall spacer proximate opposite sides of the gate structure. The method further includes performing at least two source/drain ion implant processes to form doped source/drain implant regions in the substrate that are self-aligned with respect to the sidewall spacer, wherein one of the at least two source/drain ion implant processes is performed with a dopant dose that is less than a dopant dose used in another of the at least two source/drain ion implant processes. In further, more detailed embodiments, one of the at least two source/drain ion implant processes is performed at an implant energy level that is greater than an implant energy level used in another of the at least two source/drain ion implant processes.

In yet another example, a method disclosed herein includes performing an extension implant process to form extension implant regions in a semiconducting substrate, after performing the extension implant process, forming a patterned mask layer above the substrate and performing a first source/drain implant process through the patterned mask layer to form first doped source/drain implant regions in the substrate, wherein the first source/drain implant process was performed with a first dopant dose and at a first implant energy level. The method further includes, after performing the first source/drain implant process, performing a second source/drain implant process through the patterned mask layer to form second doped source/drain implant regions in the substrate, wherein the second source/drain implant process was performed with a second dopant dose and at a second implant energy level, and wherein the first dopant dose is less than the second dopant dose and the first implant energy level is greater than the second implant energy level.

Another illustrative method disclosed herein includes forming a gate structure above a an active layer of a semiconducting substrate that comprises a buried insulation layer, performing an extension implant process to form extension implant regions in the active layer and, after performing the extension implant process, forming a sidewall spacer proximate opposite sides of the gate structure. In this embodiment, the method also includes performing a first source/drain implant process to form first doped source/drain implant regions in the active layer that are self-aligned with respect to the sidewall spacers, wherein the first source/drain implant process is performed with a first dopant dose and at a first implant energy level and, after performing the first source/drain implant process, performing a second source/drain implant process to form second doped source/drain implant regions in the active layer that are self-aligned with respect to the sidewall spacers, wherein the second source/drain implant process is performed with a second dopant dose and at a second implant energy level, and wherein the first dopant dose is less than the second dopant dose and the first implant energy level is greater than the second implant energy level.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depict one illustrative process flow for forming source/drain regions on a prior art transistor device;

FIGS. 2A-2F depict various illustrative methods of a multiple step implantation process to form source/drain regions in semiconductor devices; and

FIGS. 3A-3D reflect various testing data of devices formed using one illustrative embodiment of the multiple step implantation process disclosed herein for forming source/drain regions.

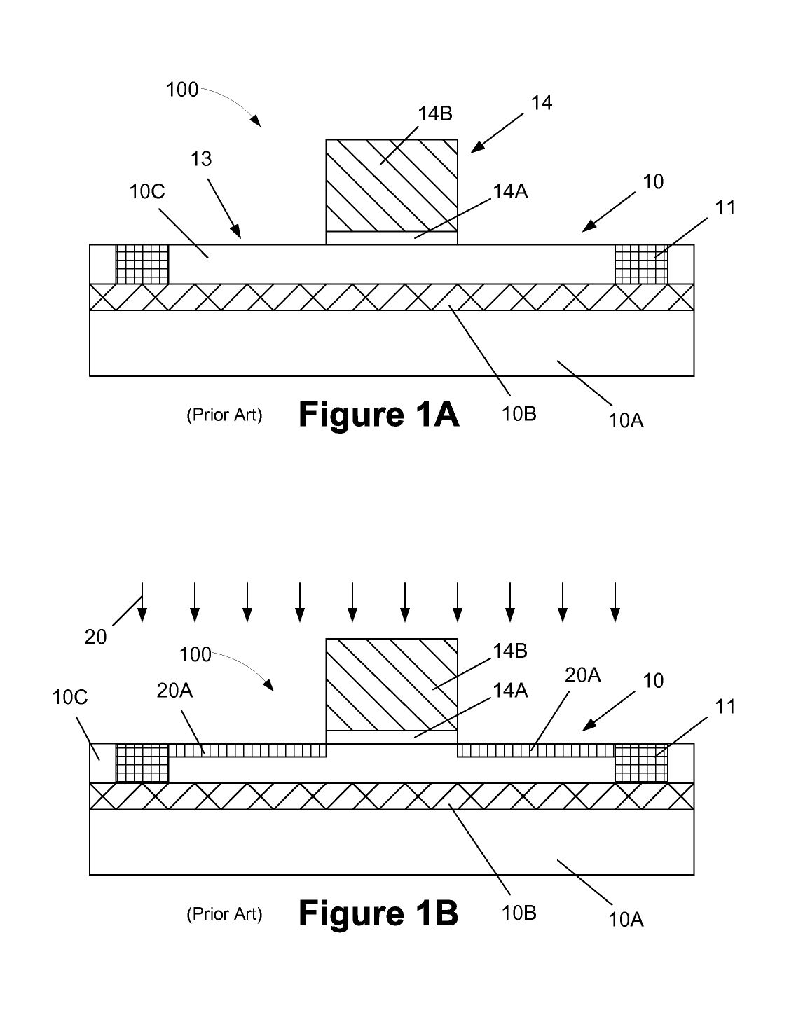

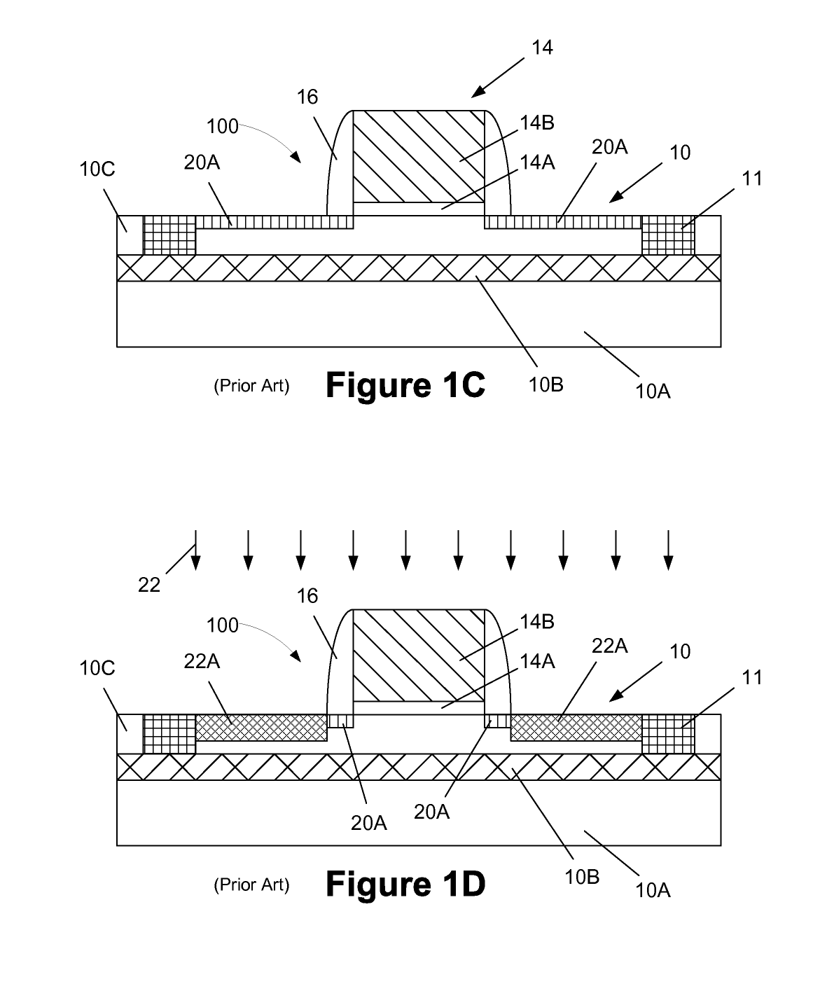

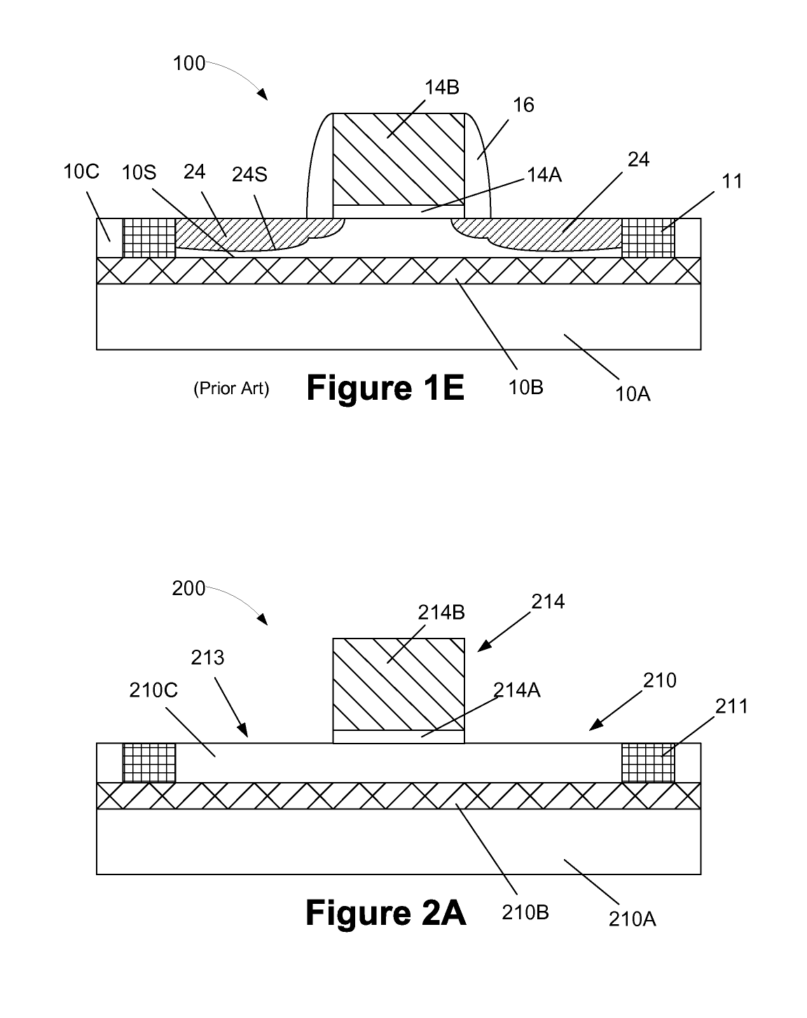

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to a multiple step implantation process to form source/drain regions in semiconductor devices, such as transistors. As will be readily apparent to those skilled in the art upon a complete reading of the present application, the present method is applicable to a variety of devices and technologies, e.g., NMOS, PMOS, CMOS, etc., and is readily applicable to a variety of integrated circuit products, including, but not limited to, ASIC's, logic devices, memory devices, etc. With reference to the attached drawings, various illustrative embodiments of the methods disclosed herein will now be described in more detail.

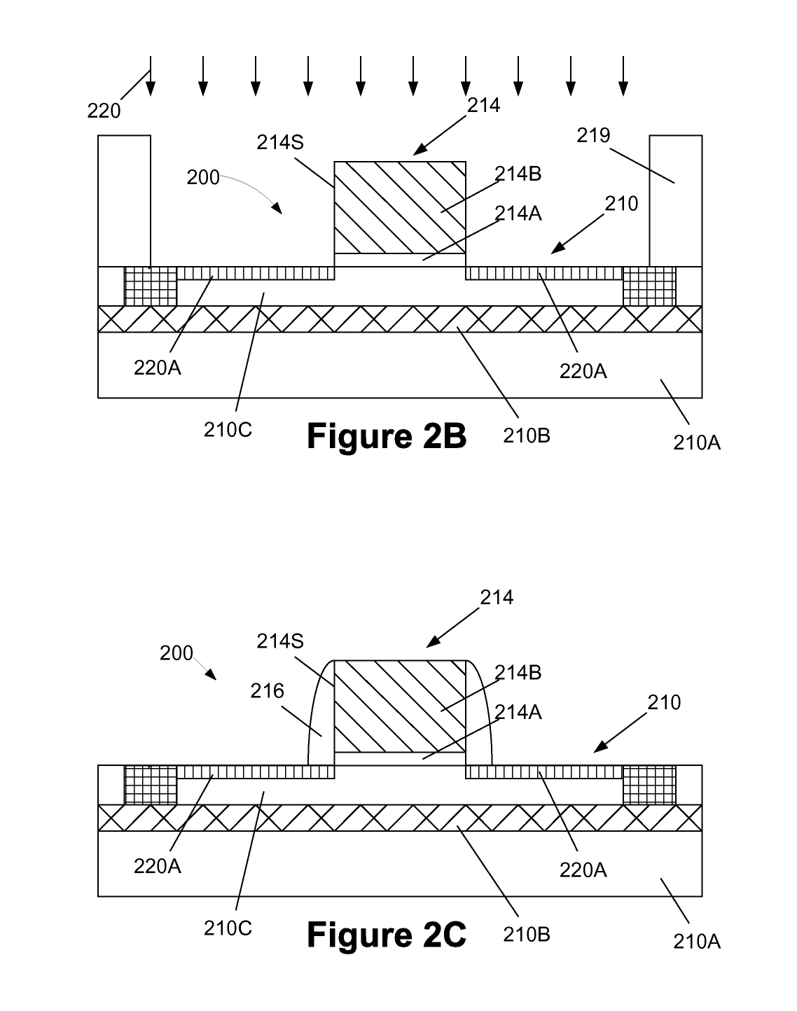

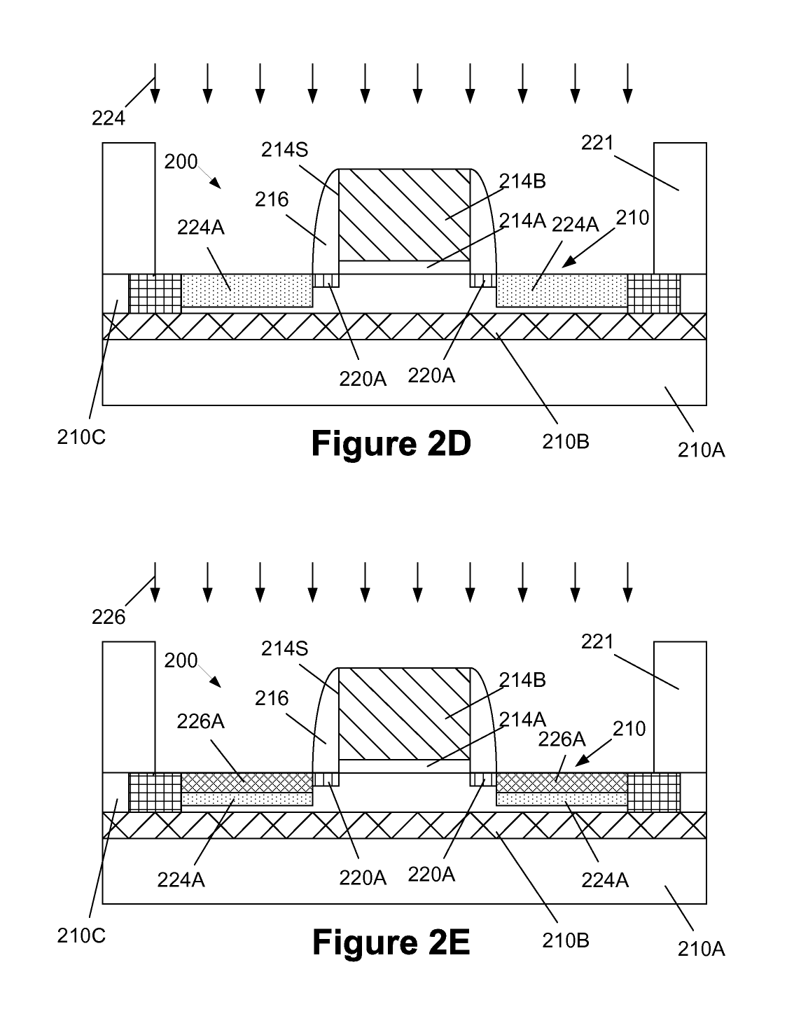

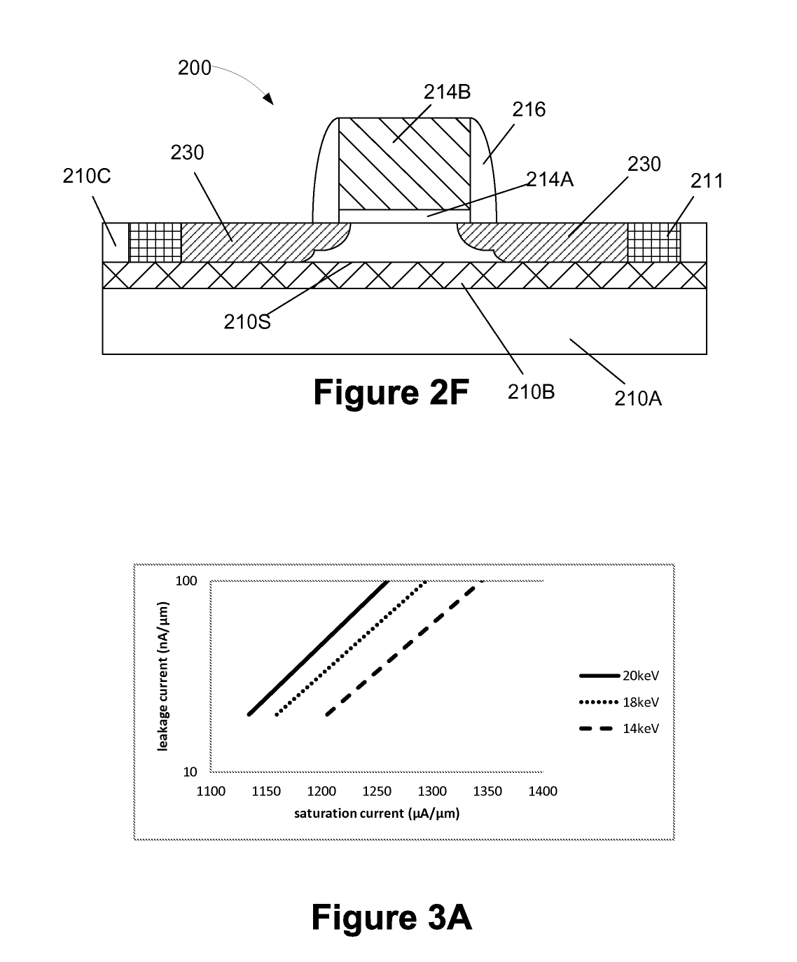

FIG. 2A depicts a transistor 200 at an early stage of fabrication, wherein a gate structure 214 has been formed above a silicon-on-insulator (SOI) substrate 210 that is comprised of a bulk substrate 210A, a buried insulation layer 210B (a so-called BOX layer) and an active layer 210C where semiconductor devices will be formed. The substrate 210 may also be made of materials other than silicon. An active region 213 is defined in the active layer 210C by a shallow trench isolation structure 211.

The gate structure 214 typically includes a gate insulation layer 214A and a conductive gate electrode 214B. The gate structure 214 may be formed by forming layers of material that correspond to the gate insulation layer 214A and the gate electrode 214B and thereafter patterning those layers of material using known etching and photolithography techniques. For example, various layers of material that correspond to the gate insulation layer 214A and the gate electrode 214A (and a gate cap layer (not shown)) may be formed above the substrate 210 by performing one or more deposition and/or thermal growth processes. Thereafter, a patterned masking layer (not shown), such as a photoresist mask, is formed above the various layers of material, and one or more etching processes are performed through the patterned masking layer to define the gate insulation layer 214A and the gate electrode 214B. As will be appreciated by one skilled in the art after a complete reading of the present application, the gate structure 214 may be formed using a variety of different materials and by performing a variety of known techniques. For example, the gate insulation layer 214A may be comprised of a variety of different insulating materials, e.g., silicon dioxide, a so-called high-k insulating material (k value greater than 10). The gate electrode 214B may be comprised of polysilicon or it may contain at least one metal layer. The gate structure 214 of the transistor 200 may be made using so-called “gate first” or “gate last” techniques. That is, the gate structure 214 that is present during the formation of the source/drain regions as described herein may be sacrificial in nature as it may be removed after the final source/drain regions of the device 200 are formed and replaced with a replacement gate structure (not shown), e.g., a high-k gate insulation layer and a gate electrode comprised of at least one metal layer. Thus, the presently disclosed inventions should not be considered as limited to any particular materials of construction for the gate structure 214 nor the manner in which such a gate structure 214 is formed.

As shown in FIG. 2B, a patterned mask layer 219, e.g., a patterned photoresist mask, is formed above the substrate 210 using known photolithography techniques. Thereafter, an initial extension region ion implantation process 220 is performed to form so-called extension implant regions 220A in the active layer 210C of the substrate 210. In some cases, the extension implant regions 220A will be self-aligned with respect to the sidewall 214S of the gate structure 214 (e.g., for an NMOS transistor in certain applications). However, in other cases, there may be an offset spacer or liner (not shown) formed on the sidewall 214S of the gate structure 214 prior to performing the extension implant process 220, and the extension implant regions 220A would be self-aligned with respect to such liner and/or spacer structure. The details of the ion implantation process 220, such as the material implanted, the implant dose and implant energy, may vary depending on the particular application. In one illustrative embodiment, where the device 200 is an NMOS transistor, the ion implantation process 220 may be a vertical ion implantation process performed using an N-type dopant, e.g., arsenic or phosphorus, at a dopant dose that ranges from about 1e¹⁴-5e¹⁵ ions/cm², at an energy level that ranges from about 1-10 keV.

Then, as shown in FIG. 2C, the patterned mask layer 219 is removed by performing, for example, an ashing process. Thereafter, after the extension implant regions 220A are formed, sidewall spacers 216 are formed proximate the gate structure 214. By use of the word “proximate,” it is meant to cover situation where the sidewall spacers 216 actually contact the sidewall 214S of the gate structure 214 as well as situations where the sidewall spacer 216 contacts a structure that was formed adjacent to or in contact with the sidewall 214S of the gate structure 214, e.g., a liner and/or spacer, prior to the formation of the sidewall spacer 216. The sidewall spacers 216 are typically formed by conformably depositing a layer of spacer material and thereafter performing an anisotropic etching process. The sidewall spacers 216 may be comprised of a variety of different materials, e.g., silicon nitride, and the base width of the spacers 216 may vary depending upon the particular application, e.g., 10-25 nm.

In one broad aspect, the present invention is directed to performing a multiple step implantation sequence, for example, a two-step ion implantation sequence, to form source/drain regions for the transistor device 200 through the same patterned mask layer. The steps may be performed in any order. In one embodiment, the dopant dose in one of the two steps is greater than the dopant dose in the other of the two steps, and the two steps may be performed in any order. In a further, more detailed embodiment, one of the steps is performed using a relatively lower dopant dose, and a relatively higher implant energy as compared to the other implant process. Of course, the implant steps may be performed in any order. Thus, the use of the terms “first” and “second” to describe various implant processes in the description below and in the claims are only for purposes of identifying the particular step, and such terms do not imply any particular order, unless the claim language requires a particular order by the use of appropriate language in the claims.

As shown in FIG. 2D, a patterned mask layer 221, e.g., a patterned photoresist mask, is formed above the substrate 210 using known photolithography techniques. There-after, as shown in FIGS. 2D-2E, a multiple step ion implantation sequence is performed through the patterned mask layer 221 to form the deep source/drain implant regions for the device 200. That is, in the depicted example, two ion implant processes are performed through the same patterned mask layer 221 to form the deep source/drain regions for the device 200. More specifically, in one illustrative example depicted in FIG. 2D, a first source/drain ion implantation process 224 is performed to form first source/drain implant regions 224A in the active layer 210C of the substrate 210. Thereafter, in this illustrative example, as shown in FIG. 2E, a second source/drain ion implantation process 226 is performed through the same patterned mask layer 221 to form second source/drain implant regions 226A in the active layer 210C of the substrate 210. Of course, as noted above, the second ion implant process 226 may be performed prior to the first ion implant process 224 if desired. Typically, the first and second source/drain implant regions 224A, 226A will be self-aligned with respect to the sidewall spacer 216.

In one more detailed illustrative example, in relative terms, the first ion implant process 224 may be performed using a relatively lower dopant dose than is used in the second ion implant process 226, while the implant energy of the first ion implant process 224 may be greater than the implant energy used in the second ion implant process 226. Stated another way, in one illustrative method, the first source/drain implant regions 224A are deeper but have a lesser dopant concentration than the second source/drain implant regions 226A which are shallower but have a relatively higher dopant concentration than do the first source/drain implant regions 224A. The absolute values of the parameters of the first and second ion implantation processes 224, 226, such as the material implanted, the implant dose and implant energy, may vary depending on the particular application, and may change as technology improves or evolves. In one illustrative embodiment, where the device 200 is an NMOS transistor, the first ion implantation process 224 may be a vertical ion implantation process performed using an N-type dopant, e.g., arsenic or phosphorus, at a dopant dose that ranges from about 1e¹³-3e¹⁵ ions/cm², at an energy level that ranges from about 5-30 keV. In one particularly illustrative embodiment, the ion implant process 224 may be performed using arsenic at a dopant dose of about 5e¹⁴ ions/cm² at an energy level of about 20 keV. In one illustrative embodiment, where the device 200 is an NMOS transistor, the second ion implantation process 226 may be a vertical ion implantation process performed using an N-type dopant, e.g., arsenic or phosphorus, at a dopant dose that ranges from about 1e¹⁴-5e¹⁵ ions/cm², at an energy level that ranges from about 5-20 keV. In one particularly illustrative embodiment, the ion implant process 226 may be performed using arsenic at a dopant dose of about 3e¹⁵ ions/cm² at an energy level of about 14 keV. Stated another way, in one illustrative embodiment, the dopant dose during the first ion implantation process 224 is at least about 33% less than the dopant dose used during the second ion implantation process 226. Additionally, in one illustrative embodiment, the implant energy level during the first ion implantation process 224 may be at least 25-30% greater than the implant energy level during the second ion implantation process 226. However, in the case where the first implant is performed using arsenic, and the second implant is performed using phosphorus, the implant energy of the first and second implant processes may be about the same. Of course, the type of dopants implanted, either N-type or P-type dopants, depends upon the type of transistor being made, i.e., an NMOS transistor or a PMOS transistor, respectively. The following are parameters for additional illustrative two-step source/drain implant processes that may be performed as described herein.
(1) first step—arsenic at a dopant dose of about 3e¹⁵ ions/cm² that is performed at an energy level of about 14 keV; second step—phosphorous at a dopant dose of about 1e¹⁴ ions/cm² that is performed at an energy level of about 12 keV;
(2) first step—phosphorous at a dopant dose of about 1e¹⁴ ions/cm² that is performed at an energy level of about 12 keV; second step—arsenic at a dopant dose of about 3e¹⁵ ions/cm² that is performed at an energy level of about 14 keV; and
(3) first step—arsenic at a dopant dose of about 3e¹⁵ ions/cm² that is performed at an energy level of about 14 keV; second step—arsenic at a dopant dose of about 5e¹⁴ ions/cm² that is performed at an energy level of about 20 keV.
   The various ion implantation processes described herein may be performed using well-known ion implantation systems that are commercially available.

Thereafter, as shown in FIG. 2F, a heating or anneal process is performed to form the final source/drain regions 230 for the transistor 200. In one example, this heating process may be a rapid thermal anneal process that is performed at a temperature of about 1000-1100° C. for a duration of a few seconds, e.g., about 1-3 seconds. This heating process repairs the damage to the lattice structure of the substrate material as a result of the implantation processes and it activates the implanted dopant materials, i.e., the implanted dopant materials are incorporated into the silicon lattice. As a result of the novel multiple-step source/drain implant sequence described above, the final source/drain regions 230 tend to “bottom-out” on the upper surface 210S of the buried insulation layer 210B as depicted in FIG. 2F. In the example depicted in FIG. 2F, the final source/drain regions 230 are depicted as bottoming-out uniformly across the upper surface 210S of the buried insulation layer 210B. However, in real-world devices, the bottoming-out of the final source/drain regions 230 may not be as uniform as depicted in FIG. 2F. By use of the novel multiple-step source/drain implant sequence described herein, at least some of the problems identified in the background section of this application may be at least reduced or perhaps eliminated.

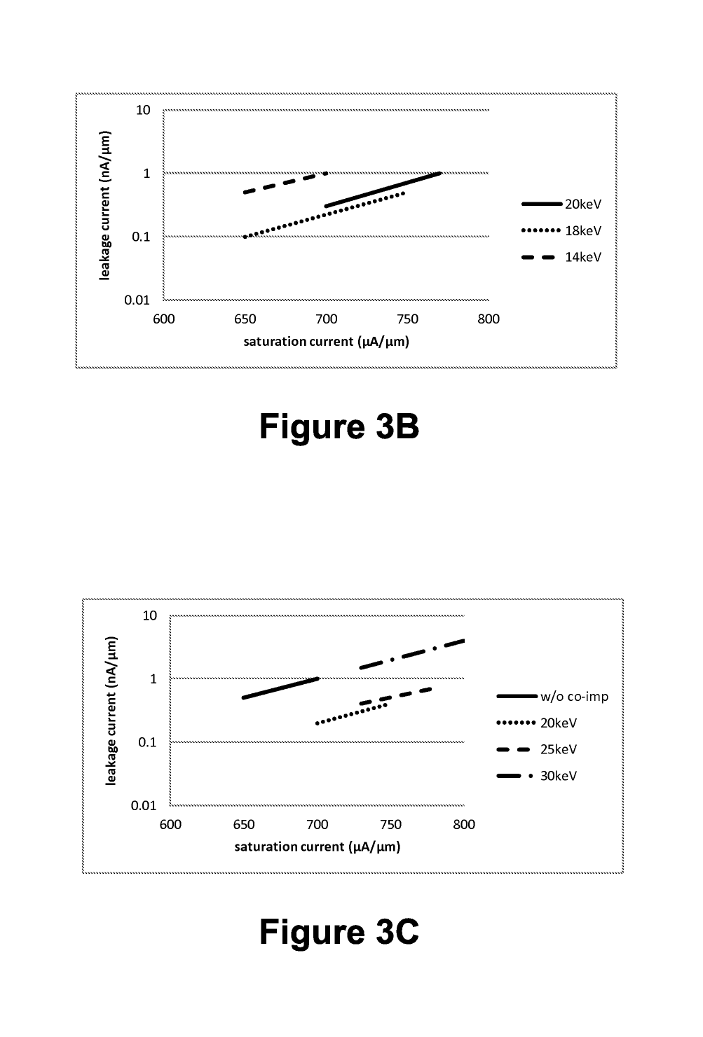

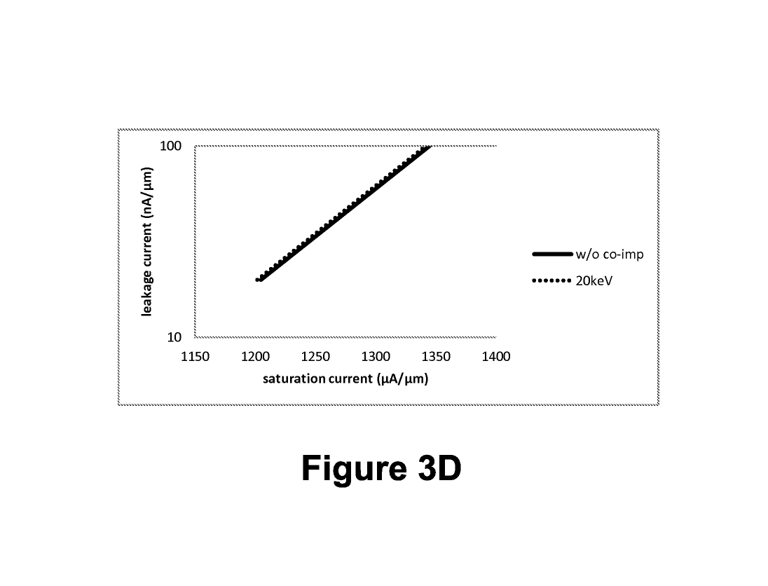

FIGS. 3A-3D reflect various testing that was done by the inventor that confirms the effectiveness and beneficial results obtained by performing the multiple step source/drain implantation sequence described above as compared to the traditional single-step source/drain implant step performed on prior art devices as described in the background section of this application. FIG. 3A is a plot of saturation current (x-axis) versus leakage current (y-axis) in log scale for a short channel NMOS transistor device subjected to a single step source/drain implant process (like the prior art) at three different implant energy levels: 20 keV, 18 keV and 14 keV. The implant processes reflected in FIG. 3A were performed using arsenic at a dopant dose of about 1e¹⁵-5e¹⁵ ions/cm². The devices had a silicon dioxide gate insulation layer with a thickness of about 1.2 nm and a polysilicon gate electrode. The devices were formed on an SOI substrate and they were subjected to an anneal process at a temperature of about 1000-1100° C. for a duration of about 1-3 seconds after the implantation processes described herein were performed. FIG. 3B is also a plot of saturation current (x-axis) versus leakage current (y-axis) for devices having a low leakage current, e.g., typically devices having a gate insulation layer that is at least about 2.5 nm or thicker, such as may be found in many input/output circuits. As can be seen in FIG. 3A, as the implant energy was decreased, the saturation current increased. More specifically, the saturation current for the case where the implant energy was about 14 keV was about 6% greater than the saturation current when the implant energy was about 20 keV. However, as shown in FIG. 3A, the leakage current was relatively high—about 100 nA/μm. FIG. 3B, which is a plot of devices having a relatively low leakage current, reflects that, for the condition where the implant energy was about 14 keV, the leakage current was higher than the other two conditions (18 keV and 20 keV). Thus, the data in FIG. 3B reflects that the source/drain regions formed using a single source/drain implant process at an energy level of about 14 keV did not effectively bottom-out on the buried insulation layer of the SOI substrate, as evidenced by the higher leakage current for this test condition.

FIG. 3C is a plot of saturation current (x-axis) versus leakage current (y-axis) in log scale for an NMOS transistor device subjected to four different implant conditions:
A—a single step source/drain ion implantation process like the prior art at 14 keV (“w/o co-imp”) using arsenic at a dopant dose of about 3e¹⁵ ions/cm²;
B—a two-step source/drain implant process as described herein with the first step being performed at 20 keV and the second step being performed at 14 keV;
C—a two-step source/drain implant process as described herein with the first step being performed at 25 keV and the second step being performed at 14 keV; and
D—a two-step source/drain implant process as described herein with the first step being performed at 30 keV and the second step being performed at 14 keV.
   In each of the conditions B, C and D, the first implant step was performed using arsenic at a dopant dose of about 5e¹⁴ ions/cm², and the second implant step was performed using arsenic at a dopant dose of about 3e¹⁵ ions/cm². As shown in FIG. 3C, condition A—the prior art single step source/drain implant process—reflected a relatively high leakage current for the devices tested. As it relates to the two-step source/drain implant processes tested, condition D (with the highest first implant energy of 30 keV) shows a relatively high leakage current as well and the highest leakage current of all of the two-step source/drain implant processes tested. As it relates to the two-step source/drain implant processes tested, condition B—with the first implant process being performed at about 20 keV and the second implant process being performed at about 14 keV—produced the lowest leakage current thereby indicating that the source/drain regions formed using the condition B process steps were more effectively bottomed-out on the buried insulation layer than source/drain regions formed using the single step source/drain implant process (condition A) of the prior art. The device subjected to implant conditions C produced results that, while better than the prior art condition A, were not as good as those achieved when using the implant processes reflected in condition B.

FIG. 3D is also a plot of saturation current (x-axis) versus leakage current (y-axis) for an NMOS transistor device, wherein two conditions are reflected:
A—a single step source/drain ion implantation process like the prior art at 14 keV (“w/o co-imp”) with a dopant does of about 3e¹⁵ ion/cm² using arsenic; and
B—a two-step source/drain implant process as described herein with the first step being performed using arsenic at a dopant dose of about 5e¹⁴ ions/cm² at an energy level of about 20 keV and the second step being performed using arsenic at a dopant dose of about 3e¹⁵ ions/cm² at an energy level of about 14 keV.
   As shown in FIG. 3D, the implementation of the two step source/drain implantation process described herein does not reduce the performance of the device as compared to the prior art devices, but it does reduce the leakage current in such devices as described previously.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
performing an extension implant process to form extension implant regions in a semiconducting substrate comprising a buried insulation layer;
after performing said extension implant process, forming a patterned mask layer above said substrate; and
performing at least two source/drain ion implant processes through said patterned mask layer to form doped source/drain implant regions in said substrate, wherein a first one of said at least two source/drain ion implant processes is performed with a dopant dose that is less than a dopant dose used to perform a second one of said at least two source/drain ion implant processes.

2. The method of claim 1, wherein said first one of said at least two source/drain ion implant processes is performed at an implant energy level that is greater than an implant energy level used to perform said second one of said at least two source/drain ion implant processes.

3. The method of claim 1, wherein said at least two source/drain ion implant processes is a two-step ion implant process.

4. The method of claim 1, wherein said first one of said at least two source/drain ion implant processes is performed prior to performing said second one of said at least two source/drain ion implant processes.

5. The method of claim 1, wherein said second one of said at least two source/drain ion implant processes is performed prior to performing said first one of said at least two source/drain ion implant processes.

6. The method of claim 1, further comprising performing an anneal process to form final source/drain regions, wherein at least a portion of the final source/drain regions contacts an upper surface of said buried insulation layer.

7. A method, comprising:
forming a gate structure above an active layer of a semiconducting substrate that comprises a buried insulation layer;
performing an extension implant process to form extension implant regions in said active layer;
after performing said extension implant process, forming a sidewall spacer proximate opposite sides of said gate structure; and
performing at least two source/drain ion implant processes to form doped source/drain implant regions in said substrate that are self-aligned with respect to said sidewall spacer, wherein a first one of said at least two source/drain ion implant processes is performed with a first dopant dose that is less than a second dopant dose used to perform a second one of said at least two source/drain ion implant processes, wherein said first one of said at least two source/drain ion implant processes is performed prior to said second one of said at least two source/drain ion implant processes.

8. The method of claim 7, wherein said first one of said at least two source/drain ion implant processes is performed at an implant energy level that is greater than an implant energy level used to perform said second one of said at least two source/drain ion implant processes.

9. The method of claim 7, further comprising performing an anneal process to form final source/drain regions, wherein at least a portion of the final source/drain regions contacts an upper surface of said buried insulation layer.

10. A method, comprising:
performing an extension implant process to form extension implant regions in a semiconducting substrate comprising a buried insulation layer;
after performing said extension implant process, forming a patterned mask layer above said substrate;
performing a first source/drain implant process through said patterned mask layer to form first doped source/drain implant regions in said substrate, said first source/drain implant process being performed with a first dopant dose and at a first implant energy level; and
after performing said first source/drain implant process, performing a second source/drain implant process through said patterned mask layer to form second doped source/drain implant regions in said substrate, said second source/drain implant process being performed with a second dopant dose and at a second implant energy level.

11. The method of claim 10, wherein said first dopant dose is less than said second dopant dose and said first implant energy level is greater than said second implant energy level.

12. The method of claim 10, wherein said first dopant dose is greater than said second dopant dose and said first implant energy level is less than said second implant energy level.

13. The method of claim 10, further comprising performing an anneal process to form final source/drain regions, wherein at least a portion of the final source/drain regions contacts an upper surface of said buried insulation layer.

14. The method of claim 10, wherein said first source/drain implant process is performed with a dose that ranges from about 1e¹³-3e¹⁵ ions/cm² at an energy level that ranges from about 5-30 keV.

15. The method of claim 10, wherein said second source/drain implant process is performed with a dose that ranges from 1e¹⁴-5e¹⁵ ions/cm² at an energy level that ranges from about 5-20 keV.

16. The method of claim 10, wherein said first dopant dose is at least about 33% less than said second dopant dose.

17. The method of claim 10, wherein said first implant energy level is at least 25% greater than said second implant energy level.

18. A method, comprising:
forming a gate structure above an active layer of a semiconducting substrate that comprises a buried insulation layer;
performing an extension implant process to form extension implant regions in said active layer;
after performing said extension implant process, forming a sidewall spacer proximate opposite sides of said gate structure;
performing a first source/drain implant process through a patterned mask layer to form first doped source/drain implant regions in said active layer that are self-aligned with respect to said sidewall spacer, said first source/drain implant process being performed with a first dopant dose and at a first implant energy level; and
after performing said first source/drain implant process, performing a second source/drain implant process through said patterned mask layer to form second doped source/drain implant regions in said active layer that are self-aligned with respect to said sidewall spacer, said second source/drain implant process being performed with a second dopant dose and at a second implant energy level.

19. The method of claim 18, wherein said first dopant dose is less than said second dopant dose and said first implant energy level is greater than said second implant energy level.

20. The method of claim 18, wherein said first dopant dose is greater than said second dopant dose and said first implant energy level is less than said second implant energy level.

21. The method of claim 18, further comprising performing an anneal process to form final source/drain regions, wherein at least a portion of the said source/drain regions contacts an upper surface of said buried insulation layer.

22. The method of claim 21, wherein said anneal process is performed at a temperature of about 1000-1100° C. for a duration of at least about 1 second.

23. The method of claim 18, wherein said gate structure is a sacrificial gate structure.

24. The method of claim 18, wherein said gate structure comprises a high-k gate insulation layer and at least one metal layer.

25. The method of claim 18, wherein said gate structure comprises a silicon dioxide gate insulation layer and a polysilicon gate electrode.

26. The method of claim 18, wherein said first source/drain implant process is performed with a dose that ranges from about 1e¹³-3e¹⁵ ions/cm² at an energy level that ranges from about 5-30 keV.

27. The method of claim 18, wherein said second source/drain implant process is performed with a dose that ranges from about 1e¹⁴-5e¹⁵ ions/cm² at an energy level that ranges from about 5-20 keV.

28. The method of claim 18, wherein said first dopant dose is at least about 33% less than said second dopant dose.
